(19) United States
(12) Patent Application Publication
(10) Pub. No.: US 2020/0185883 A1
(43) Pub. Date: Jun. 11, 2020

(54) NITRIDE SEMICONDUCTOR LASER DEVICE AND METHOD FOR PRODUCING NITRIDE SEMICONDUCTOR LASER DEVICE

(71) Applicant: SHARP KABUSHIKI KAISHA, Sakai City (JP)

(72) Inventors: TOHRU MURATA, Sakai City (JP); YUHZOH TSUDA, Sakai City (JP)

(21) Appl. No.: 16/704,854

(22) Filed: Dec. 5, 2019

Related U.S. Application Data
(60) Provisional application No. 62/778,216, filed on Dec. 11, 2018.

(51) Int. Cl. H01S 5/22; H01S 5/32

(52) U.S. Cl. CPC H01S 5/2216; H01S 5/3202

(57) ABSTRACT

A nitride semiconductor laser device includes an n-type semiconductor layer, an active layer, and a p-type semiconductor layer which are formed in this order on a nitride semiconductor substrate, and by using crystal stress in the n-type semiconductor layer, the laser device is allowed to have two or more light-emitting points emitting light with different peak wavelengths in the active layer. A method for producing a nitride semiconductor laser device includes a step of forming an n-type semiconductor layer on a nitride semiconductor substrate, a step of forming an active layer on the n-type semiconductor layer, and a step of forming a p-type semiconductor layer on the active layer. In the step of forming the n-type semiconductor layer, the n-type semiconductor layer is formed so as to produce a stress difference in a portion of the n-type semiconductor layer.

### BACKGROUND OF INVENTION

### Technical Field

The present invention relates to a nitride semiconductor laser device including an n-type semiconductor layer, an active layer, a p-type semiconductor layer which are formed in this order on a nitride semiconductor substrate, particularly a nitride semiconductor laser device having two or more light-emitting points with different peak wavelengths, and relates to a method for producing a nitride semiconductor laser device.

### Related Art

Some nitride semiconductor laser devices each including an n-type semiconductor layer, an active layer, and a p-type semiconductor layer, which are formed in this order on a nitride semiconductor substrate, have two or more light-emitting points with different peak wavelengths (refer to, for example, Japanese Patent No. 3149962). In detail, the nitride semiconductor laser device described in Japanese Patent No.3149962 has a configuration in which a plurality of resonators having different resonator lengths are arranged in parallel in an array form in the transverse direction so as to oscillate light with a wavelength corresponding to each of the bandgaps of a plurality of light-emitting layers, so that current can be independently injected into each of the plurality of resonators.

In order to form two or more light-emitting points having different peak wavelengths in such a nitride semiconductor laser device, a plurality of steps are required to be repeated for forming resonators having different resonator lengths (light-emission wavelength difference), thereby complicating a production process. Also, reflection films cannot be uniformly formed on the end surfaces of the resonators because of differences between the resonator lengths of the resonators, leading to possibility of failing to obtain stable characteristics.

In addition, a problem of the present invention is described by taking as an example a usual nitride semiconductor laser device shown in FIG. 11.

FIG. 11 is a perspective view showing a section of a schematic configuration of an example of a usual nitride semiconductor laser device 100X. As shown in FIG. 11, the usual nitride semiconductor laser device 100X has a semiconductor laminated structure on a nitride semiconductor substrate 1. Specifically, an n-type semiconductor layer 110X, an active layer 8, and a p-type semiconductor layer 120 are formed in this order on the nitride semiconductor substrate 1. In this example, in the n-type semiconductor layer 110X, an n-type AlGaN layer 2, an n-type AlGaN layer 3, an n-type InGaN layer 4X, an n-type AlGaN clad layer 5, an n-type GaN layer 6, and an n-type InGaN guide layer 7 are formed from the nitride semiconductor substrate 1 side. In this example, in the p-type semiconductor layer 120, a p-type InGaN guide layer 9, p-type AlGaN electron block layer 10, a p-type AlGaN clad layer 11, and a p-type GaN contact layer 12 are formed from the nitride semiconductor substrate 1 side. In addition, a p-side contact electrode 301 is formed on the p-type GaN contact layer 12, and a protective film 401 and a p-side pad electrode 501 are further formed. On the other hand, an n-side electrode 201 is formed on the nitride semiconductor substrate 1 on the side opposite to the n-type semiconductor layer 110X. Ridge stripe structures are connected in parallel by the p-side pad electrode 501.

The active layer 8 constitutes a light-emitting layer composed of, for example, InₓGa_{1-y}N (0<x≤1, 0<y≤1). The active layer 8 emits light by recombination of electrons, injected from the n-type semiconductor layer 110X, and holes injected from the p-type semiconductor layer 120. The light is confined between the n-type AlGaN clad layer 5 and the p-type AlGaN clad layer 11, and is propagated in the direction perpendicular to the lamination direction of the semiconductor laminated structure. The end surfaces of the resonator are formed at both ends in the propagation direction, and light is oscillated and amplified by repeated stimulated emission between a pair of the resonator end surfaces and is partially emitted as laser light from the resonator end surfaces. The emitted laser light has a single mode.

In the nitride semiconductor laser device 100X having the configuration described above, in order to obtain the different light-emission wavelengths (light-emission wavelength difference) for respective channels, different steps are required to be performed for the respective channels, depending on the control factors such as the ridge width W (largest width) of each of the channels, resonator length L, film formation conditions of the end surfaces, etc. In addition, in the nitride semiconductor laser device 100X including the active layer 8 containing In, the light-emission wavelength depends on the In composition of the active layer 8, but In is substantially uniformly incorporated into the active layer 8, and the light-emission wavelength of each of the channels is required to be controlled by the control factors such as the ridge width W, resonator length L, the film formation conditions for the end surfaces, etc. as described above, thereby sometimes failing to obtain stable characteristics.

Accordingly, it is an object of the present invention to provide a nitride semiconductor laser device which includes an n-type semiconductor layer, an active layer, and a p-type semiconductor layer formed in this order on a nitride semiconductor substrate and which can simplify a production process for forming two or more light-emitting points having different peak wavelengths and can securely obtain stable characteristics, and also to provide a method for producing a nitride semiconductor laser device.

### SUMMARY OF INVENTION

The present invention provides the following nitride semiconductor laser device and method for producing a nitride semiconductor laser device.

[1] According to an embodiment of the present invention, a nitride semiconductor laser device includes an n-type semiconductor layer, an active layer, and a p-type semiconductor layer formed in this order on a nitride semiconductor substrate, and by using crystal stress in the n-type semiconductor layer, the laser device is allowed to have two or more light-emitting points emitting light with different peak wavelengths in the active layer.

(2) According to an embodiment of the present invention, a nitride semiconductor laser device has, in addition to the configuration (1) described above, different crystal surfaces in a region of the n-type semiconductor layer.

(3) According to an embodiment of the present invention, a nitride semiconductor laser device has, in addition to the configuration (1) or configuration (2) described above, two or more ridge stripe portions formed in the p-type semiconductor layer and a concave-convex stripe structure formed in a region of the n-type semiconductor layer to extend along the direction parallel or substantially parallel to the direction in which the ridge stripe portions are formed.

(4) According to an embodiment of the present invention, a nitride semiconductor laser device includes, in addition to the configuration (3) described above, the n-type semiconductor layer including a plurality of n-type semiconductor layers and the concave-convex stripe structure which is a concave-convex pattern structure containing a first region having, as the surface, a first n-type semiconductor layer among the plurality of n-type semiconductor layers and a second region having, as the surface thereof, a plurality of second n-type semiconductor layers formed at intervals, on the first n-type semiconductor layer, in a stripe shape along the direction parallel to or substantially parallel to the direction in which the ridge stripe portions are formed.

(5) According to an embodiment of the present invention, a nitride semiconductor laser device includes, in addition to the configuration (4) described above, a third n-type semiconductor layer formed on the concave-convex stripe structure and having the same or different composition as or from the second n-type semiconductor layer.

(6) According to an embodiment of the present invention, a method for producing a nitride semiconductor laser device includes a step of forming an n-type semiconductor layer on a nitride semiconductor substrate, a step of forming an active layer on the n-type semiconductor layer, and a step of forming a p-type semiconductor layer on the active layer, the step of forming the n-type semiconductor layer including forming the n-type semiconductor layer so as to generate a stress difference in a portion of the n-type semiconductor layer.

(7) According to an embodiment of the present invention, a method for producing a nitride semiconductor laser device includes, in addition to the configuration (6) described above, forming different crystal surfaces in a region of the n-type semiconductor layer in the step of forming the n-type semiconductor layer.

(8) According to an embodiment of the present invention, a method for producing a nitride semiconductor laser device includes, in addition to the configuration (6) or configuration (7) described above, forming two or more ridge stripe portions in the p-type semiconductor layer in the step of forming the p-type semiconductor layer on the active layer, and forming, in a region of the n-type semiconductor layer, a concave-convex stripe structure extending along the direction parallel or substantially parallel to the direction, in which the ridge stripe portions are formed, in the step of forming the n-type semiconductor layer.

(9) According to an embodiment of the present invention, a method for producing a nitride semiconductor laser device includes, in addition to the configuration (8) described above, forming a plurality of n-type semiconductor layers as the n-type semiconductor layer and forming as, the concave-convex stripe structure, a concave-convex pattern structure containing a first region having, as the surface, a first re-type semiconductor layer and a second region having, as the surface, a plurality of second n-type semiconductor layers formed at intervals, on the first n-type semiconductor layer, in a stripe shape along the direction parallel or substantially parallel to the direction in which the ridge stripe portions are formed.

(10) According to an embodiment of the present invention, a method for producing a nitride semiconductor laser device includes, in addition to the configuration layer described above, forming a third n-type semiconductor layer having the same or different composition as or from the second n-type semiconductor layer on the concave-convex stripe structure in the step of forming the n-type semiconductor layer.

According to the present invention, it is possible to simplify a production process for forming two or more light-emitting points having different peak wavelengths, and to obtain stable characteristics.

### BRIEF DESCRIPTION OF DRAWINGS

FIG. 1 is a schematic perspective view showing a section of the laminated structure of a nitride semiconductor laser device according to Example 1.

FIG. 2 is a schematic sectional view showing the nitride semiconductor laser device according to Example 1.

FIG. 3 is a schematic sectional view showing a production process for the nitride semiconductor laser device according to Example 1.

FIG. 4 is a schematic perspective view showing a production process for the nitride semiconductor laser device according to Example 1.

FIG. 5 is a schematic perspective view showing a production process for the nitride semiconductor laser device according to Example 1.

FIG. 6 is a schematic sectional view showing a production process for the nitride semiconductor laser device according to Example 1.

FIG. 7 is a schematic sectional view showing a production process for the nitride semiconductor laser device according to Example 1.

FIG. 8 is a schematic sectional view showing a production process for the nitride semiconductor laser device according to Example 1.

FIG. 9 is a schematic sectional view showing a production process for the nitride semiconductor laser device according to Example 1.

FIG. 10 is a schematic sectional view showing a nitride semiconductor laser device according to Example 2.

FIG. 11 is a perspective view showing a section of a schematic configuration of an example of a usual nitride semiconductor laser device.

### DESCRIPTION OF EMBODIMENTS

Embodiments of the present invention are described below with reference to the drawings. In the description below, the same component is denoted by the same reference numeral. The name and function thereof are also the same. Therefore, the detailed description thereof is not repeated.

### EXAMPLE 1

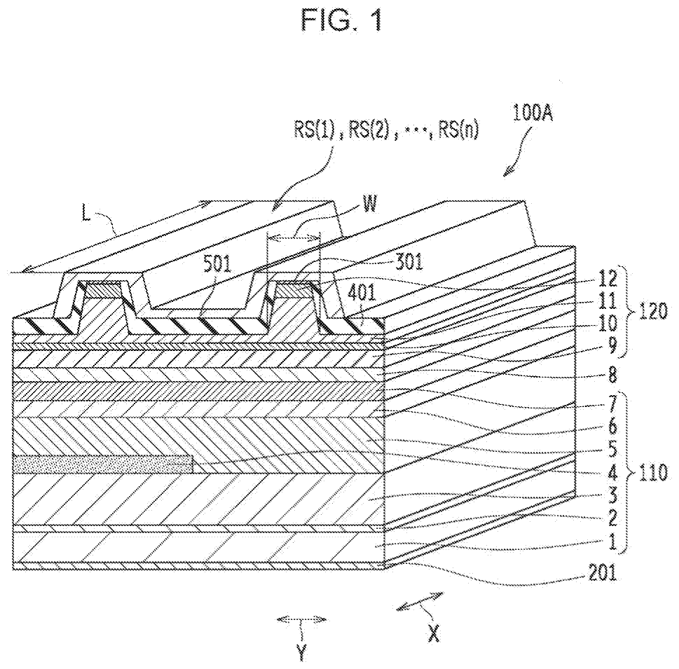

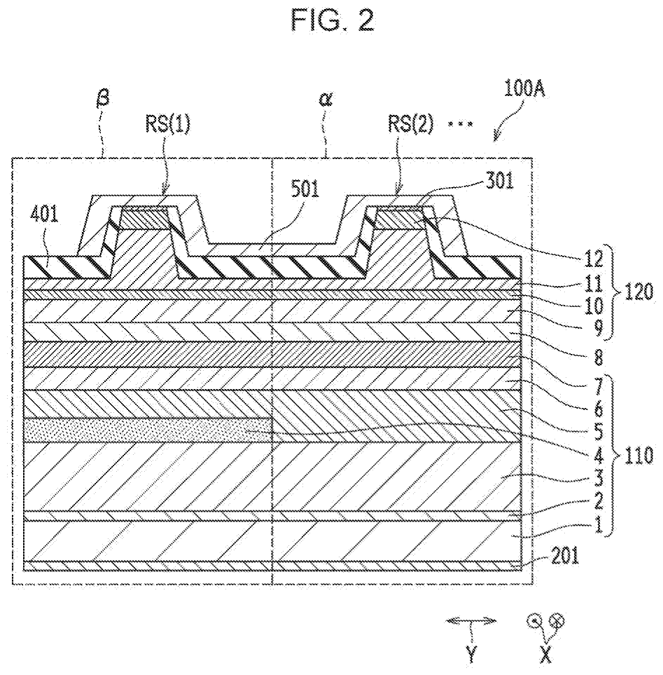

FIG. 1 is a schematic view showing a section of the laminated structure of a nitride semiconductor laser device 100A according to Example 1. FIG. 2 is a schematic sectional view showing the nitride semiconductor laser device 100A according to Example 1.

As shown in FIG. 1 and FIG. 2, the nitride semiconductor laser device 100A has a semiconductor laminated structure on a nitride semiconductor substrate 1. Specifically, an n-type semiconductor layer 110, an active layer 8, and a p-type semiconductor layer 120 are formed in this order on the nitride semiconductor substrate 1.

In detail, in this example, in toe n-type semiconductor layer 110, an n-type AlGaN layer 2, an n-type AlGaN layer 3, an n-type InGaN layer 4, an n-type AlGaN clad layer 5, an n-type SaN layer 6, and an n-type InGaN guide layer 7 are formed from the nitride semiconductor substrate 1 side. The n-type InGaN layer 4 extends along the resonator length direction X and includes a plurality of n-type InGaN layers arranged in parallel at predetermined intervals in the width direction Y perpendicular to the resonator length direction X (refer to FIG. 4 described below).

Specifically, after the n-type InGaN layer 4 in the n-type semiconductor layer 110 is laminated, a concave-convex stripe structure having the n-type AlGaN layer 3 as a bottom is formed in the direction parallel or substantially parallel to the direction (resonator length direction X) in which ridge stripe portions are formed. In this case, as shown in FIG. 2, a region not containing the n-type InGaN layer 4 but having the n-type AlGaN layer 3 as the surface is referred to as a “first region α”, and a region having the n-type InGaN layer 4 as the surface is referred to as a. “second region β”.

A nitride semiconductor layer is further laminated on a nitride semiconductor layer having the concaves and convexes formed therein and being composed of the n-type InGaN layer 4. The first region α and the second region β have different compositions of In taken in the active layer 8 because of a difference in stress applied to the active layer 8.

The n-type AlGaN clad layer 5, the n-type GaN layer 6, and the n-type InGaN guide layer 7 are formed on the n-type AlGaN layer 3 and the n-type InGaN layer 4.

In this example, in the p-type semiconductor layer 120, a p-type InGaN guide layer 9, p-type AlGaN electron block layer 10, a p-type AlGaN clad layer 11, and a p-type GaN contact layer 12 are formed from the nitride semiconductor substrate 1 side. In addition, ridge stripe portions RS (1) to RS (n) are formed to such a depth as not to reach the p-type AlGaN electron block layer 10, and a p-side contact electrode 301 is formed on the ridge stripe portions RS (1) to RS (n), a protective film 401 is formed from the side surfaces to toe bottom surfaces of the ridge stripe portions RS (1) to RS (n), and further a p-side pad electrode 501 is formed on the p-side contact electrode 301 and the protective film 401. On the other hand, an n-side electrode 201 is formed on the nitride semiconductor substrate 1 on the side opposite to the n-type semiconductor layer 110X.

In the nitride semiconductor laser device 100A having the configuration, well layers having different compositions are formed in a multiple quantum well structure by growth on different crystals. That is, a difference in lattice constants causes a difference in stress applied to the active layer 8 grown on a region having the concaves and convexes formed therein and being composed of the n-type InGaN layer 4, thereby permitting the division into regions having high and low In compositions taken in the active layer 8 (light-emitting layer). In detail, the light-emission wavelength of each channel is determined by the in composition taken in the active layer 8. Thus, a difference can be made between the light-emission wavelengths of the first region α and the second region β. For example, when a plurality of ridge stripe portions RS (1) to RS (n) are connected in parallel by the p-side pad electrode 501, different light-emission wavelengths can be simultaneously obtained by one p-side pad electrode 501.

[Nitride Semiconductor Substrate 1]

A GaN substrate is preferably used as the nitride semiconductor substrate 1, and a substrate provided with conductivity by adding Si as an n-type impurity can be used. In the nitride semiconductor laser device 100A including the nitride semiconductor substrate 1 having a Si-containing configuration, series resistance can be decreased by moving current in the lamination direction of the layers, thereby simplifying a chip structure.

(N-Type AlGaN Layer 2)

The n-type AlGaN layer 2 is an n-type AlGaN layer composed of Alₐ₁Ga₁₋ₐ₁N (0<a1≤1), and the Al composition ratio is preferably 15% or more and 30% or less.

(N-Type AlGaN Layer 3)

The n-type AlGaN layer 3 is an n-type AlGaN layer composed of Alₐ₂Ga₁₋ₐ₂N (0<a2≤1), the Al composition ratio is preferably 1% or more and 5% or less, and the thickness is preferably 1000 nm to 2000 nm. The n-type AlGaN layer 3 can suppress the light leaking from the active layer 8 (light-emitting layer) to the nitride semiconductor substrate 1 side and can suppress miscellaneous light.

(N-Type InGaN Layer 4)

The n-type InGaN layer 4 is an n-type InGaN layer composed of Inₐ₃Ga₁₋ₐ₃N (0<a3≤0.1). The n-type InGaN layer 4 can suppress cracking of the n-type InGaN layer 4 due to an AlGaN layer having a high Al composition.

(N-Type AlGaN Clad Layer 5)

The n-type AlGaN clad layer 5 is an n-type AlGaN clad layer composed of Alₐ₄Ga₁₋ₐ₄N (0<a4≤1). The n-type AlGaN clad layer 5 enables the satisfactory confinement of light within a light-emitting region. The Al composition ratio of the n-type AlGaN clad layer is preferably 5% or more. In order to prevent cracking, the Al composition ratio is preferably 10% or less, and the thickness is preferably 800 nm to 1200 nm.

(N-Type GaN Layer 6)

The n-type GaN layer 6 is preferably formed to a thickness of 100 nm to 400 nm. Therefore, residual strain can be relieved, and crystallinity can be recovered.

The two layers including the n-type AlGaN clad layer 5 and the n-type GaN layer 6 are preferably doped with Si. In this case, the Si concentration is preferably 1×10¹⁸/cm³ to 3×10¹⁸/cm³. Therefore, conductivity can be secured. Here, “dope” represents that a conductive impurity is intentionally added to a semiconductor crystal, and “doped semiconductor layer” represents a semiconductor layer to which a conductive impurity is added. Also, “undope” represents the state of a semiconductor crystal to which a conductive impurity is not intentionally added, and the concept thereof includes semiconductor crystal such that an impurity such as C, H, O, Cl, or the like or a conductivity-controlling impurity having substantially no influence on conductivity is inevitably mixed during crystal growth.

(N-Type InGaN Guide Layer 7)

The n-type InGaN guide layer 7 is an n-type InGaN guide layer composed of Inₐ₃Ga₁₋ₐ₅N (0.01≤a5≤0.15). The In composition ratio in the n-type InGaN guide layer 7 is preferably 1% to 5%. The n-type InGaN guide layer 7 is grown by using InGaN constituting the n-type InGaN guide layer 7, and thus the light confinement efficiency can be enhanced. The thickness of the n-type InGaN guide layer 7 is preferably 150 nm to 200 nm and is preferably an undoped layer for preventing deterioration in crystallinity. The n-type InGaN guide layer 7 can improve the light emission efficiency of well layers in the active layer 8.

(Active Layer 8)

The active layer 8 preferably has a multiple quantum well structure in which a plurality of Inₐ₆Ga_{1-b6}N (0<a6≤1, 0<b6≤1) well layers and a plurality of Inₐ₇Ga_{1-b7}N (0≤a7<1, 0≤b7<1) barrier layers are alternately formed. For example, the active layer 8 can be formed with a double quantum well structure including the barrier layers and the well layers and starting with the barrier layer and ending with the barrier layer. Among these, preferably, the barrier layers are GaN layers, and the well layers are InGaN layers. The barrier layers have the effect of recovering crystallinity. The well layers are preferably made of a nitride semiconductor material having lower bandgap energy than the barrier layers, and InGaN is particularly preferred. The atomic composition ratio in the well layers is not particularly limited and can be arbitrarily selected according to the wavelength for oscillation. The active layer 8 emits light from the plurality of well layers and thus the plurality of layers preferably have the same In composition ratio and thickness in order to maintain monochromaticity. The thicknesses of the plurality of barrier layers can be respectively changed.

(P-Type InGaN Guide Layer 9)

The p-type InGaN guide layer 9 is an n-type InGaN guide layer composed of Inₐ₈Gaₐ₈N (0.01≤a8≤0.15). The p-type InGaN guide layer 9 is an InGaN layer having the same In composition ratio and thickness as those of the p-type InGaN guide layer. The larger the thickness of the p-type InGaN guide layer and the n-type InGaN guide layer is, the more the light confinement efficiency can be improved. Therefore, the In composition ratios of these layers can be suppressed, and deterioration in crystallinity due to an increase in thickness as an uncoped layer can be prevented.

(P-Type AlGaN Electron Block Layer 10)

The p-type AlGaN electron block layer 10 is a p-type AlGaN electron block layer composed of Alₐ₉Ga₁₋ₐ₉N (0.01≤a9<1). The Al composition ratio of the p-type AlGaN electron block layer 10 is preferably 15% to 30%. In addition, in order to make the p-type AlGaN electron block layer 10 p-type, it mainly contains Mg as a p-type impurity, and Mg is preferably added at a concentration of 1×10¹⁸/cm³ to 9×10¹⁸/cm³. The thickness of the p-type AlGaN electron block layer is preferably 5 nm to 15 nm. The p-type AlGaN electron block layer has these conditions and thus can suppress the leakage (overflow) of electrons not recombined with holes in the active layer 8, among the electrons injected into the active layer 8 from the n-type semiconductor layers, to the p-type AlGaN clad layer 11 side. Thus, while the injection efficiency can be improved, the threshold current can be decreased. Also, an increase in resistance can be prevented due to the small thickness.

(P-Type AlGaN Clad layer 11)

The p-type AlGaN clad layer 11 is a p-type AlGaN clad layer composed of Alₐ₁₀Ga₁₋ₐ₁₀N (0<a10<1). The Al composition ratio of the p-type AlGaN clad layer 11 is preferably 3% to 5%. In addition, in order to make the p-type AlGaN clad layer p-type, it mainly contains Mg as a p-type impurity, and Mg is preferably added at a concentration of 1×10¹⁸/cm³ to 9×10¹⁸/cm³. The thickness of the p-type AlGaN clad layer is preferably 600 nm to 800 nm. The p-type AlGaN clad layer has these conditions and thus has a lower refractive index than the active layer and can confine light. Thus, the prevention of cracking and a decrease in resistance can be realized due to the low Al composition ration.

(P-Type GaN Contact Layer 12)

The p-type GaN contact layer 12 mainly contains Mg as a p-type impurity, and the Mg concentration is preferably 2×10¹⁹/cm³ to 9×10¹⁹/cm³. The thickness of the p-type GaN contact layer is preferably about 50 nm to 150 nm. Thus, the p-type GaN contact layer can decrease contact resistance and series resistance

(P-Side Contact Electrode 301)

The p-side contact electrode 301 composed of pd (palladium) and having a thickness of 50 nm can be formed on the surface of the p-type GaN contact layer 12.

(Ridge Stripe Portion RS)

The two or more ridge stripe portions RS (1) to RS (n) can be formed by partially etching the p-type GaN contact layer 12 and the p-type AlGaN clad layer 11 by a photolithographic method. The ridge width (W) of the ridge stripe portions RS (1) to RS (n) can be adjusted to 1.5 μm to 2 μm.

(Protective Film 401)

Further, the protective film 401 composed of SiO₂ can be formed on the exposed side surfaces of the ridge stripe portions RS (1) to RS (n) and the etching-exposed surface of the p-type AlGaN clad layer 11.

(P-Side Pad Electrode 501)

The p-side pad electrode 501 including, in order, Ti with a thickness of 15 nm and Au with a thickness of 800 nm can be formed on the p-side contact electrode 301 and the protective film 401.

(N-Side Electrode 201)

The n-side electrode 201 including Ti with a thickness of 15 nm and Au with a thickness of 40 nm in order from the nitride semiconductor substrate 1 side can be formed on the surface (back surface) of the nitride semiconductor substrate 1 on the side opposite to the n-type semiconductor layer 110X.

<Method for Producing Nitride Semiconductor Laser Device 100A According to Example 1>

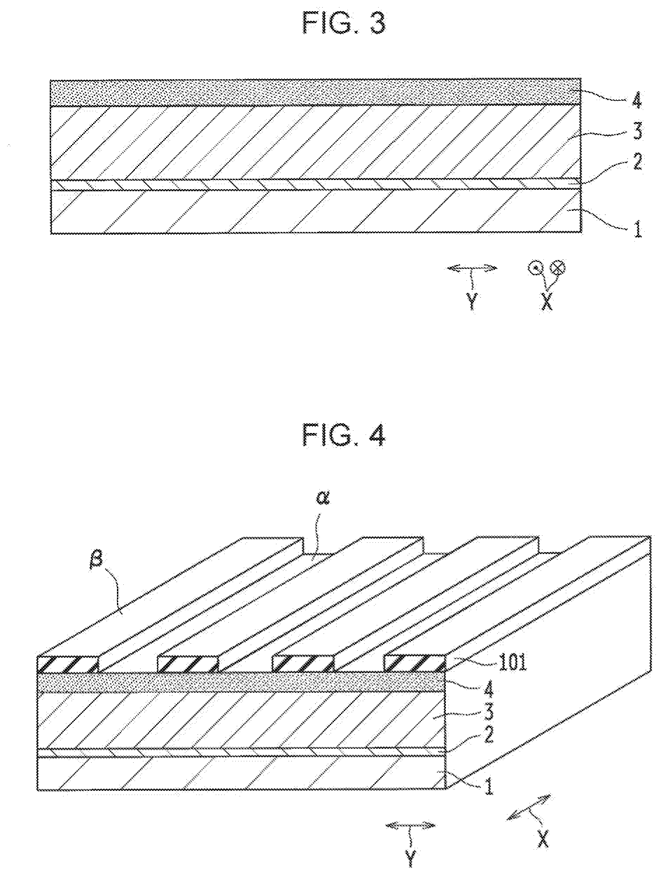

Next, the method for producing the nitride semiconductor laser device 100A according to Example 1 is described. FIG. 3 to FIG. 9 are explanatory drawings for explaining the process for producing the nitride semiconductor laser device 100A according to Example 1.

In producing the nitride semiconductor laser device 100A according to Example 1, as shown in FIG. 3, first the n-type AlGaN layer 2 composed of Al_{0.15}Ga_{0.80}N is grown to a thickness of about 5 nm on the nitride semiconductor substrate 1 using nitrogen as carrier gas, ammonia (NH₃), TMG (trimethyl gallium), and TMA (trimethyl aluminum) as raw material gas, and SiH₄ (monosilane) as impurity gas at a growth temperature of 930° C. on the nitride semiconductor substrate 1. In this case, the impurity concentration in the n-type AlGaN layer 2 is preferably 1×10¹⁹ cm⁻³ or more.

After the growth of the n-type AlGaN layer 2, only TMG, TMA, and SiH₄ are stopped, and the temperature is increased to 1130° C. After the temperature becomes 1130° C., the n-type AlGaN layer 3 composed of Al_{0.015}Ga_{0.985}N is grown to a thickness of about 1500 nm using hydrogen as carrier gas, and, similarly using TMG and TMA as raw material gas and SiH₄ as impurity gas.

Next, the temperature is decreased to 830° C., and the n-type InGaN layer 4 composed of In_{0.04}Ga_{0.96}N is grown to a thickness of 160 nm using nitrogen as carrier gas, and similarly using TMG, TMI (trimethyl indium), and ammonia as raw material gas and SiH₄ as impurity gas, and then a wafer is taken out from a production apparatus after the temperature is decreased.

As shown in FIG. 4, a stripe-shape pattern at intervals of about 120 μm is formed in the direction parallel or substantially parallel to the resonator length direction X by photolithography on the wafer on which the layers up to the n-type InGaN layer 4 have been grown, and then the SiO₂ film 101 is formed to about 300 nm.

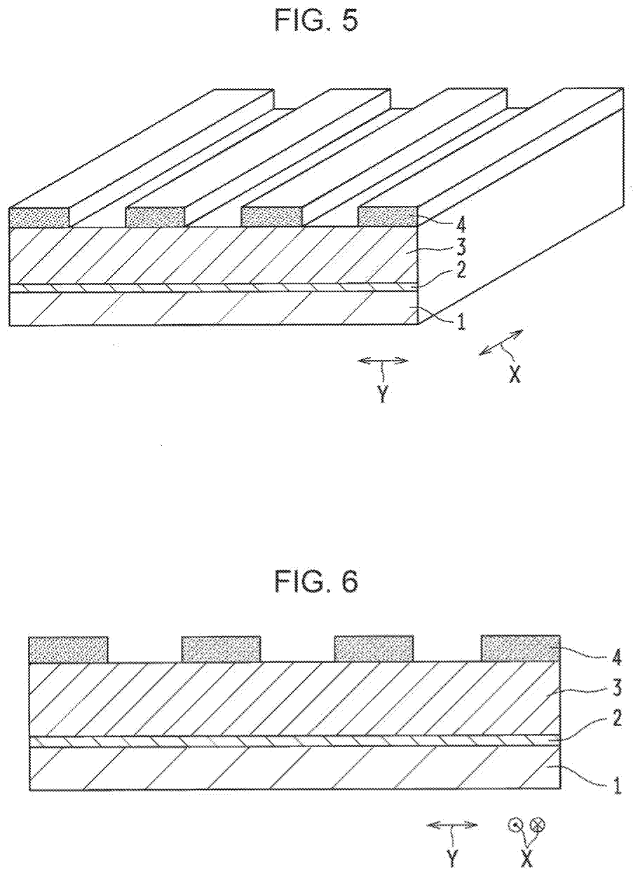

After the SiO₂ film 101 is formed, dry etching is performed until the surface of the n-type AlGaN layer 3 is reached, forming, as shown In FIG. 5, a concave-convex pattern with a pitch of 240 μm, which includes the first region α having the n-type AlGaN layer 3 as the surface and the second region β having the n-type InGaN layer 4 as the surface.

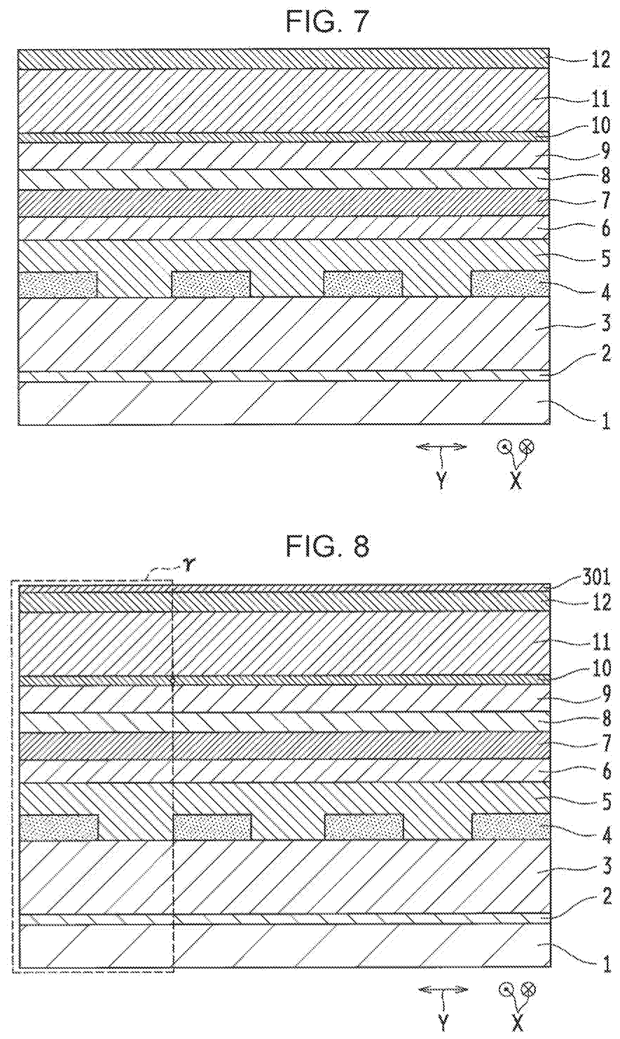

Next, as shown in FIG. 6 and FIG. 7, the nitride semiconductor layer, in which concaves and convexes including the first region α and the second region β have been formed, is again installed in the production apparatus, the temperature is increased to 1130° C., and then the n-type AlGaN clad layer 5 composed of Al_{0.087}Ga_{0.913}N is grown to a thickness of 850 nm using hydrogen as carrier gas, and ammonia, TMG, and TMA as raw material gas. Then, only TMA as raw material gas is stopped, and the n-type GaN layer 6 is grown to a thickness of 300 nm.

Next, the growth temperature is set to 840° C., and the n-type InGaN guide layer 7 composed of In_{0.032}Ga_{0.968}N is grown to a thickness of 180 nm using nitrogen as carrier gas, and TMG and TMI as raw material gas. Then, the growth temperature is set to 700° C., and the active layer 8 composed of InGaN/GaN and having two light-emitting layers is grown. The light-emitting layers are grown by using TMG and TMI as raw material gas, and a barrier layer is grown by using TEG (triethyl gallium).

Next, the growth temperature is set to 840° C., and the p-type InGaN guide layer 9 composed of In_{0.031}Ga_{0.969}N is grown to a thickness of 170 nm using TMG and TMI. Then, the p-type AlGaN electron block layer 10 composed of Al_{0.16}Ga_{0.84}N is grown to a thickness of 6 nm using TMG and TMA as raw material gas and Cp2Mg (cyclopentadienyl magnesium) as impurity gas while the growth temperature is increased to 1105° C. Then, the p-type AlGaN clad layer 11 composed of Al_{0.04}Ga_{0.96}N is grown to a thickness of 650 nm using hydrogen as carrier gas, and finally only TMA is stopped, and the p-type GaN contact layer 12 is grown to a thickness of 80 nm.

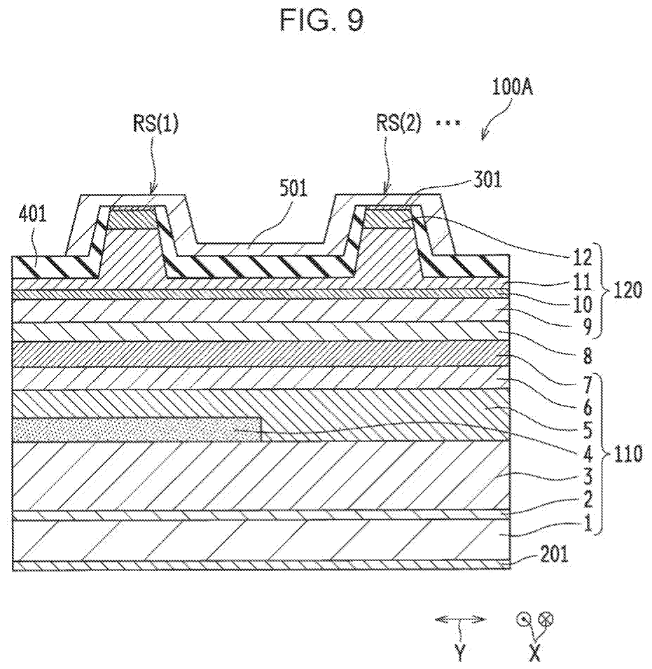

Next, as shown in FIG. 8, Pd (palladium) is deposited to a thickness of 50 nm to form the p-side contact electrode 301 on the p-type semiconductor layer 120 side surface. Then, as shown in FIG. 9, the ridge stripe portions RS (1) to RS (n) with a width of 1.8 μm are formed on the first region α and the second regions β, and the protective film 401 is formed by using SiO₂ from the side surfaces to the ends of the ridge stripe portions RS. FIG. 9 shows a portion after the treatment of a portion γ shown in FIG. 8.

Next, the p-side pad electrode 501 composed of Ti/Au with thicknesses 15 nm/800 nm, respectively, in this order is formed. Finally, the n-side electrode 201 composed of Ti/Au with thicknesses 15 nm/40 nm, respectively, in this order is formed.

In the nitride semiconductor laser device 100A described above, the use of crystal stress in the n-type semiconductor layer 110 allows to have two or more light-emitting points emitting light with different peak wavelengths in the active layer 8. When two or more light-emitting points with different peak wavelengths are obtained by using crystal stress in the n-type semiconductor layer 110, a multi-wavelength semiconductor laser device having different light emission wavelengths can be produced by the same process without through a usual complicated process performed for obtaining a light-emission wavelength difference. Therefore, the production process can be simplified. In addition, the light-emission wavelength of each channel need not be controlled by the control factors such as the ridge width W (largest width) of the ridge stripe portions RS (1) to RS (n), resonator length L, film formation conditions for the end surfaces, etc., and thus stable characteristics can be, securely obtained. In addition, a treatment for obtaining a light-emission wavelength difference can be performed by the same process without changing the ridge width W and resonator length as usual.

In addition, in the nitride semiconductor laser device 100A, the n-type semiconductor layer 110 has a region having different crystal surfaces from each other. Thus, it is possible to easily realize a configuration in which the use of crystal stress in the n-type semiconductor layer 110 allows to have two or more light-emitting points emitting light with different peak wavelengths in the active layer 8.

In addition, in the nitride semiconductor laser device 100A, the two or more ridge stripe portions RS (1) RS (n) (n is an integer of 2 or more) are formed in the p-type semiconductor layer 120. The concave-convex stripe structure is formed in a region of the n-type semiconductor layer 110 to extend in the direction parallel or substantially parallel to the direction (resonator length direction X) in which the ridge stripe portions RS (1) to RS (n) are formed. Thus, it is possible to realize a waveguide structure which confines light in a horizontal direction by the ridge stripe portions RS (1) to RS (n), and the ridge stripe portions RS (1) to RS (n) can be imparted with two or more light-emitting points, respectively, which emit light with different peak wavelength in the active layer 8.

In addition, in the nitride semiconductor laser device 100A, the n-type semiconductor layer 110 includes a plurality of n-type semiconductor layers. The concave-convex stripe structure is a concave-convex pattern structure including the first region α and the second region β. The first region a has, as the surface, the first n-type semiconductor layer (the n-type AlGaN layer 3) among the plurality of n-type semiconductor layers 110. The second region β has, as the surface, a plurality of second n-type semiconductor layers (the n-type InGaN layer 4) formed at intervals, on the first n-type semiconductor layer (the n-type AlGaN layer 3), in a stripe shape in the direction parallel or substantially parallel to the direction (resonator length direction X) in which the ridge stripe portions are formed. Therefore, a difference occurs in the stress applied to the active layer 8 grown on a region where concaves and convexes are formed, and thus the active layer 8 (light-emitting layer) can be divided into a region with nigh In intake and a region with low In intake.

### EXAMPLE 2

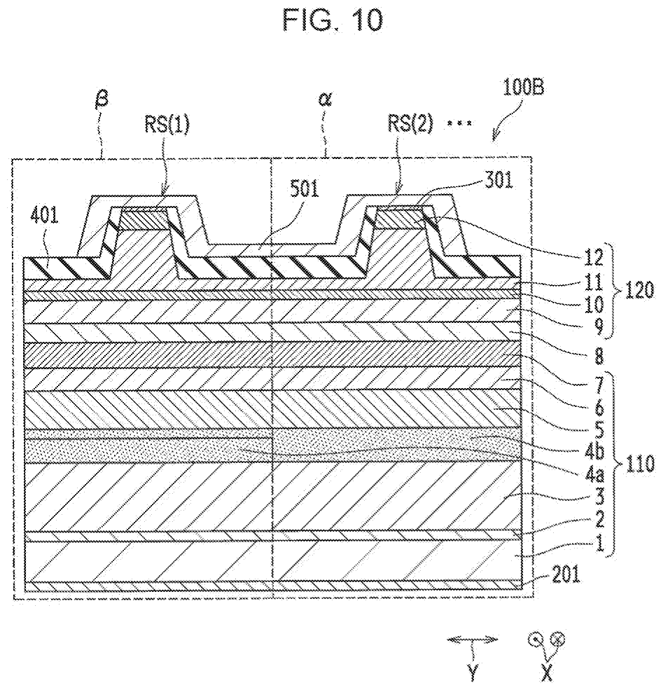

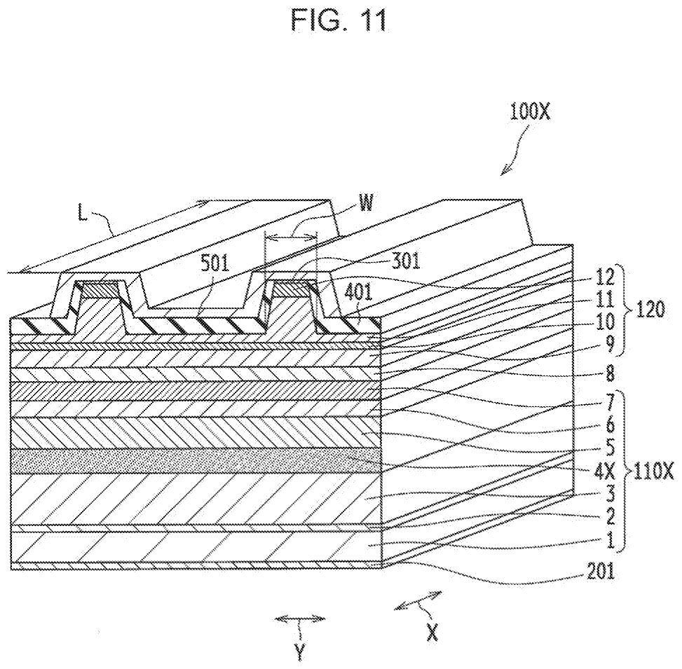

FIG. 10 is a schematic sectional view showing a nitride semiconductor laser device 100B according to Example 2.

As shown in FIG. 10, in the nitride semiconductor laser device 100B according to Example 2, a third n-type semiconductor layer (n-type InGaN layer 4b) having the same or different composition as or from the composition of a second n-type semiconductor layer (n-type InGaN semiconductor layer 4a) is formed on a concave-convex stripe structure. This can decrease the thickness of the n-type AlGaN semiconductor clad layer 5. In this case, the composition ratio in the n-type InGaN layer 4a can be made the same as that in the n-type InGaN semiconductor layer 4 in the nitride semiconductor laser device 100A according to Example 1. In addition, the composition ratio of the n-type InGaN layer 4b can be made the same as or different from (In composition ratio higher than that of the n-type InGaN layer 4a) that of the n-type InGaN layer 4a.

Next, a method for producing the nitride semiconductor laser device 100B according to Example 2 is described. The method for producing the nitride semiconductor laser device 100B according to Example 2 includes the same steps as those for the nitride semiconductor laser device 100A according to Example 1 up to the step of, after forming the SiO₂ layer 101, dry etching until the surface of the n-type AlGaN layer 3 is reached, forming the concave-convex pattern with a pitch of 240 μm which includes the first region α having the n-type AlGaN layer 3 as the surface and the second region β having the n-type InGaN layer 4 as the surface.

FIG. 10 shows a production process after the formation of the concave-convex pattern in the nitride semiconductor laser device 100B according to Example 2.

As shown in FIG. 10, after the concave-convex pattern is formed, the n-type InGaN layer 4b having the same or different In composition is formed on the nitride semiconductor layer in which the first region α and the second region β have been formed, and grown thereon are the n-type AlGaN clad layer 5, the n-type GaN layer 6, the n-type InGaN guide layer 7, the active layer 8, the p-type InGaN guide layer 9, the p-type AlGaN electron block layer 10, the p-type AlGaN clad layer 11, and the p-type GaN contact layer 12.

Next, the ridge stripe portions RS (1) to RS (n) are formed, in the direction substantially parallel to the pitch of the concave-convex pattern, to such a depth as not to reach the p-type AlGaN electron block layer 10 on the surface side of the p-type semiconductor layer 120.

The subsequent steps are the same as those for the nitride semiconductor laser device 100A according to Example 1, and the description thereof is omitted therein.

The present invention is not limited to the embodiments described above and can be embodied in other various forms. Therefore, the embodiments are only examples different from each other in all respects and should not be restrictively understood. The scope of the present invention is indicated by the claims and not restricted by the specification. Further, all the modifications and changes coming within the range of equivalency of the claims are therefore within the scope of the present invention.

1. A nitride semiconductor laser device comprising an n-type semiconductor layer, an active layer, and a p-type semiconductor layer which are formed in this order on a nitride semiconductor substrate,
wherein by using crystal stress in the n-type semiconductor layer, the laser device is allowed to have two or more light-emitting points emitting light with different peak wavelengths in the active layer.

2. The nitride semiconductor laser device according to claim 1,
wherein the n-type semiconductor layer has a region having different crystal surfaces.

3. The nitride semiconductor laser device according to claim 1,
wherein two or more ridge stripe portions are formed in the p-type semiconductor layer; and
a concave-convex stripe structure extending along the direction parallel or substantially parallel to the direction in which the ridge stripe portions are formed is formed in a region of the n-type semiconductor layer.

4. The nitride semiconductor laser device according to claim 3,
wherein the n-type semiconductor layer includes a plurality of n-type semiconductor layers; and
the concave-convex stripe structure is a concave-convex pattern structure which includes a first region having, as the surface, a first n-type semiconductor layer among the plurality of n-type semiconductor layers, and a second region having, as the surface, a plurality of second n-type semiconductor layers formed at intervals on the first n-type semiconductor layer in a stripe form along the direction parallel or substantially parallel to the direction in which the ridge stripe portions are formed.

5. The nitride semiconductor laser device according to claim 4,
wherein a third n-type semiconductor layer having the same or different composition as or from the second n-type semiconductor layer is formed on the concave-convex stripe structure.

6. A method for producing a nitride semiconductor laser device, comprising:
a step of forming an n-type semiconductor layer on a nitride semiconductor substrate;
a step of forming an active layer on the n-type semiconductor layer; and
a step of forming a p-type semiconductor layer on the active layer,
wherein in the step of forming the n-type semiconductor layer, the n-type semiconductor layer is formed so as to produce a stress difference in a portion of the n-type semiconductor layer.

7. The method for producing a nitride semiconductor laser device according to claim 6,
wherein in the step of forming the n-type semiconductor layer, different crystal surfaces are formed in a region of the n-type semiconductor layer.

8. The method for producing a nitride semiconductor laser device according to claim 6,
wherein in the step of forming the p-type semiconductor layer on the active layer, two or more ridge stripe portions are formed in the p-type semiconductor layer; and
in the step of forming the n-type semiconductor layer, a concave-convex structure is formed in a region of the n-type semiconductor layer to extend along the direction parallel or substantially parallel to the direction in which the ridge stripe portions are formed.

9. The method for producing a nitride semiconductor laser device according to claim 8,
wherein the n-type semiconductor layer includes a plurality of n-type semiconductor layers; and
in the step of forming the n-type semiconductor layer, a concave-convex pattern structure is formed as the concave-convex stripe structure, which includes a first region having, as the surface, a first n-type semiconductor layer among the plurality of n-type semiconductor layers, and a second region having, as the surface, a plurality of second n-type semiconductor layers formed at intervals on the first n-type semiconductor layer in a stripe form along the direction parallel or substantially parallel to the direction in which the ridge stripe portions are formed.

10. The method for producing a nitride semiconductor laser device according to claim 9,
wherein in the step of forming the n-type semiconductor layer, a third n-type semiconductor layer having the same or different composition as or from the second n-type semiconductor layer is formed on the concave-convex stripe structure.
